(19) United States
(12) Patent Application Publication
(10) Pub. No.: US 2024/0276670 A1
(43) Pub. Date: Aug. 15, 2024

(54) INTERCONNECTABLE DATA CENTER EQUIPMENT RACK

(71) Applicant: TRITON METALS, INC., Hollywood, MD (US)

(72) Inventors: Jason Wayne NORRIS, Hollywood, MD (US); William Maurice OWENS, SR., Charlotte Hall, MD (US); Christopher Warren POOLE, Leonardtown, MD (US)

(73) Assignee: TRITON METALS, INC., Hollywood, MD (US)

(21) Appl. No.: 18/108,291

(22) Filed: Feb. 10, 2023

(51) Int. Cl. H05K 7/14; H05K 5/02

(52) U.S. Cl. CPC H05K 7/1488; H05K 5/0221; H05K 7/1418

(57) ABSTRACT

A data center equipment rack includes openings in RF-shielded walls allow for a shielded electromagnetic connection between two or more racks. A plenum between adjoining racks increases protection from electromagnetic pulses. At least one access door in the enclosure is provided for facilitating access to the electronic equipment in the rack. Each access door has a latch which presses the door toward the rack, compressing a gasket to ensure a tight seal between the door and rack. A floating hinge connects the door to the rack.

### BACKGROUND OF THE INVENTION

This invention relates to a scalable rack system for commercial Information Technology (IT), control, and communications equipment. The development of “data centers”, often referred to as “the cloud”, has evolved over the last couple of decades to support IT needs of companies, governments and individuals. The growth and expansion of the internet has allowed for the centralizing of “IT Processing” in such data centers.

Most enterprises in government, military, and industry rely on critical applications that are frequently hosted in central data processing hubs—whether commercial or proprietary data centers. Today, much, if not all internet commerce is dependent upon data centers. Data centers allow for enterprises to centralize and scale the specialized hardware and support staff required to operate their critical applications. Additionally, the data centers allow for the centralizing of support systems such as power, cooling, communication bandwidth, backup power, maintenance, software upgrades and many other functions that are costly for individual entities to maintain and operate. Commercial offerings such as “Amazon Web Services” host small-scale applications for individuals and industry as well as large-scale applications such as Netflix with large data processing, storage and bandwidth requirements. Banking and financial entities have been centralizing IT operations in data centers for many years as computer processing has become more advanced and data storage costs have become far less expensive and more reliable. Government, including the military, intelligence community and other critical functions are hosting critical applications in data centers.

Data centers are by definition repositories of high-density computing equipment—processors, memory storage and the like. The capacity of these systems is continually being increased as cost is further reduced and additional applications are developed. These repositories are ideally designed and built to provide rapidly scalable architecture to accommodate frequent capacity additions. One aspect of this scalability is the development of rack systems which house the equipment. IT equipment has evolved into processing, communications, and storage elements that are housed in racks having a standard-sized profile. These are defined in EIA-310, the Electronic Industries Alliance standard for “Cabinets, Racks, Panels, and Associated Equipment”. This standard defines the dimensions and support requirements for standard profile electronic equipment. It defines a “Rack Unit” (RU, or sometimes simply “U”) to express the requirements for mounting electronic equipment that complies with the EIA-310 standard. Most IT equipment dimensions are expressed in “U” units which implies that it can be installed in a compliant “server rack”. This necessarily simplifies the scaling of IT capacity, which is critical to data center construction and operations.

A parallel concern that arises as the size of and reliance on these very large data centers increases is the danger of damage to the data centers from electromagnetic pulses, malicious or otherwise, which can destroy or significantly impair the operation of a data center. As a result of this concern, Electromagnetic Pulse (“EMP”) protection protocols have been and are being developed to protect critical data centers. In March of 2019, an Executive Order titled “Executive Order on Coordinating National Resilience to Electromagnetic Pulses” was issued.

Data centers are defined by the US Government as “Critical Infrastructure” and, as such, it must be protected from various threats, including natural disasters and protection of data centers against electromagnetic threats, such as EMP. This includes the entire threat family such as Nuclear Electromagnetic Pulse—from the detonation of a nuclear fission device at high-altitude, Intentional Electromagnetic Interference (“IEMI”) and natural phenomena such as Geomagnetic Disturbances (GMD, or “Solar Storms”).

Data centers are nodes of vulnerability for any advanced economy—government, finance, commerce, water utilities, power utilities, transportation, military, national security, among other basic functions of an advanced economy all depend on data centers and communication between data centers and end user applications. The loss, even a temporary loss, of functionality would have very large cascading effects upon such an economy.

Principles of protection against electromagnetic threats are known and defined. The US military has published the non-classified “MIL-STD-188-125” standard (hereafter “MIL-STD”) as well as other publications that provide for the specification and shielding of critical functions within an environment that is protected against electromagnetic threats. Additionally, the intelligence community has articulated “TEMPEST” requirements that prevent electronic emanations from being released from electronic equipment that could be exploited and decoded by an adversary. EMP/IEMI shielding prevents electromagnetic energy originating outside of a protected environment from entering and damaging systems inside the protected environment.

TEMPEST shielding prevents electromagnetic emanations that originate inside a protected environment from exiting and possibly being exploited by “Bad Actors” outside of the protected environment.

In typical IT/Data Center installations, racks are either “Open” (facilitating cooling, power, interconnection between racks) or “Enclosed” which allows for some control over access to equipment in individual racks, but also facilitates the connection/interconnection of racked equipment with other racks, power, and communications equipment required for IT systems and applications to operate. Each connection for power, communications, cooling, as well as any doors on racks to facilitate access is a potential vulnerability to EMP/HEMP/IEMI and TEMPEST.

“Electromagnetically secure” as used in this application means that electromagnetic field levels will not exceed MIL-STD-188-125-1/2, IEMI levels will not exceed EN55035, and Tempest ICD/ICS 705. These are not the only electromagnetic shielding performance standards, and the rack system is not tied to any specific standard. The rack system is expected to perform from 10 khz (or lower) to 10 ghz (or higher) frequency to a level where electromagnetically induced damage, disruption, upset, exploitation, as well as the physical protection of the contents of the racks is reliably accomplished. The rack systems include the use of cypher locks, card-reader access, magnetic latching or other physical protection means to present access by unauthorized personnel.

### SUMMARY OF THE INVENTION

A rack system includes interconnected racks having the interconnection ports of two racks aligned. A plenum connected at the interconnection ports creates a secure seal and protection between electromagnetic pulses. In addition, the latches on the doors each rack press inwardly to compress a gasket and create a tight seal between the door and rack body. A floating hinge allows the doors to be biases inwardly when compressing the gasket.

### BRIEF DESCRIPTION OF THE DRAWING FIGURES

The present invention is best understood when the following detailed description of the invention is read with reference to the accompanying drawings, in which:

FIG. 1 is a front isometric view of a data center equipment rack according to a preferred embodiment of the invention;

FIG. 2 is a rear isometric view of the data center equipment rack shown in FIG. 1;

FIG. 3 is a front elevation showing an array of data center equipment racks;

FIG. 4 is a front perspective view of a plenum;

FIG. 5 is a cross section view of a plenum attached between two data center equipment racks;

FIG. 6 is a perspective view of a door of the data center equipment rack;

FIG. 7 is an exploded view of a latch for the door;

FIG. 8 is an exploded view of a hinge for the door; and

FIG. 9 is a cross sectional view of the hinge attached to the data center equipment rack.

### DETAILED DESCRIPTION OF THE PREFERRED EMBODIMENT

The development of the rack system as described in this application is directed towards the purpose of providing an electromagnetically secure environment within which any item, including IT equipment, communications equipment, control equipment, protective relay equipment, or any other electronic or non-electronic item may be placed. As described below, the described racks and rack system are interconnectable—above, below, beside, or through a protected umbilical structure.

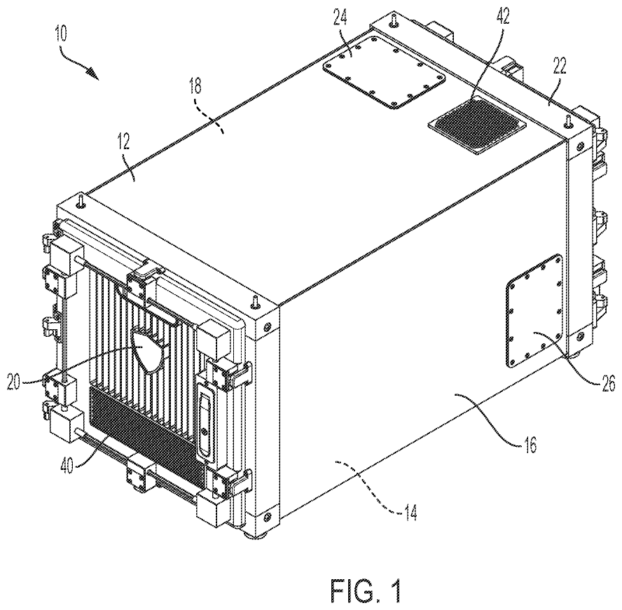

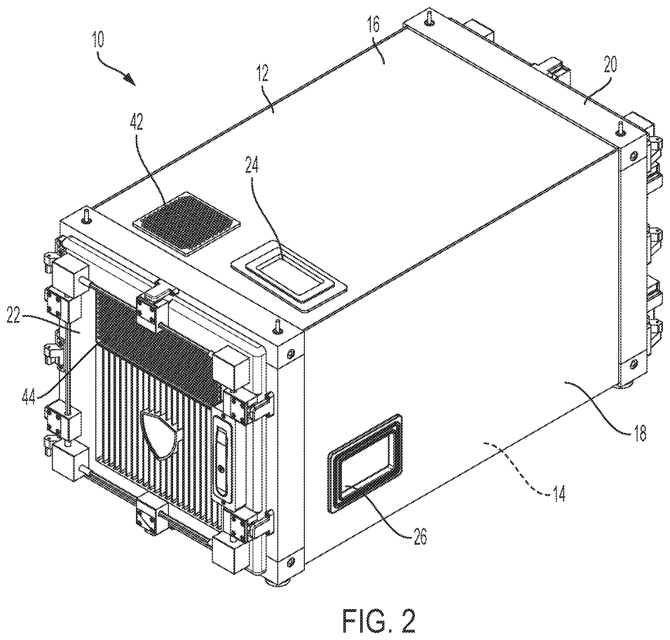

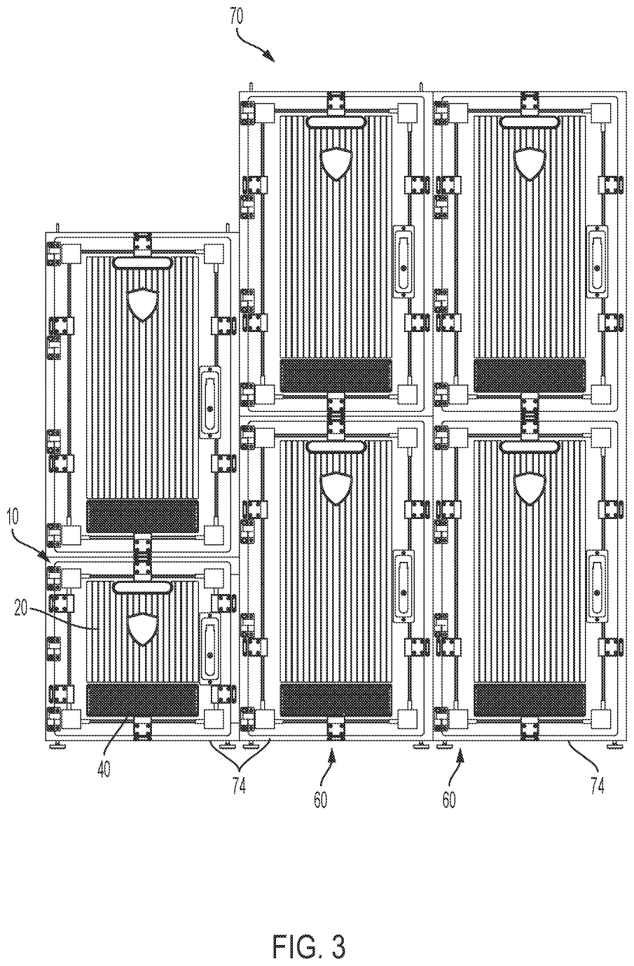

As shown in FIGS. 1 and 2, the rack 10 is generally rectangular and includes a top wall 12, a bottom wall 14, a pair of side walls 16, 18, a front wall 20 and a back wall 22. The top wall 12 includes a removable cover 24, and the side walls 16, 18 have a removable cover 26, 28. The removable covers 24, 26 and 28 cover interconnection ports aligning with openings in adjacent racks 10 above or below the rack 10 without regard to the size of the racks 10 to define a rack system 70 as shown in FIG. 3.

With the covers 24, 26 and 28 removed, interconnection ports 24A, 26A and 28A are exposed for use. The size and location of the interconnection ports 24A, 26A and 28A can be of any size and location, as long as the ports 24A, 26A and 28A align with ports in adjacent racks 10.

Referring to FIGS. 1 and 2, air intake/exhaust port 40 in the front wall 20, air intake/exhaust port 42 in the top wall 12, air intake/exhaust port 43 in the bottom wall 14 and air intake/exhaust port 44 in the rear wall 22 are standard “waveguide below cutoff” intakes that pass air but not electromagnetic energy. This is a standard approach and not an innovation per se.

The air intake/exhausts 40, 42, 44 can be any size and in any location to accommodate specific needs of the user. As evident by its description, the air intake/exhausts 40, 42, 44 may either take cooling air into the rack 10 or exhaust warm air from the rack 10 depending on the direction of fan rotation. See by way of example, fan 46 of air intake/exhaust 44.

The racks 10 may be combined into multi-rack assemblies to form a rack system 70 shown in FIG. 3. As described above, the arrangement of individual racks 10 may be dictated by a wide variety of requirements and racks may be different sizes and dimensions as long as the covers are matched and aligned when mated together. In FIG. 9 a rack 10 as described above is shown assembled with five (5) racks of a larger size to form the rack system 70. Dimensions support standard racks but this does not need to be the case. Racks can be taller, wider and deeper as required for the application. By way of example, a 10U rack 10 may have dimensions as follows: 24.75 in. (62.9 cm.) wide, 23.75 in. (60 cm.) high and 47.8 in. (121.5 cm.) deep. These dimensions support standard racks but this does not need to be the case. Racks can be taller wider and deeper as required for the application. The depictions shown in this application are one possible version of many possible rack designs. The racks can be taller, wider, or be sized to support any standard or non-standard rack unit mounting of equipment.

These can include versions with more, fewer, larger or smaller interconnection ports using any shape interconnection port cover. The racks 10 can have as many interconnection ports as required. Also, the interconnection ports facilitate the integration of special penetrations, as needed, by allowing for electromagnetically sealed penetrations for waveguides, air, liquid, fiber optic ports, or penetrations for any other purpose to be integrated into any available rack interconnection port.

The rack 10 includes air waveguides, provisions for filters and other items. Because the racks 10 are interconnectable, each individual rack 10 does not need to have a filter, rather it can be connected to power in another rack 10 through the interconnection ports 24A, 26A and/or 28A. Similarly, air flow, data cables, or any other required connection can be routed between racks 10 as needed.

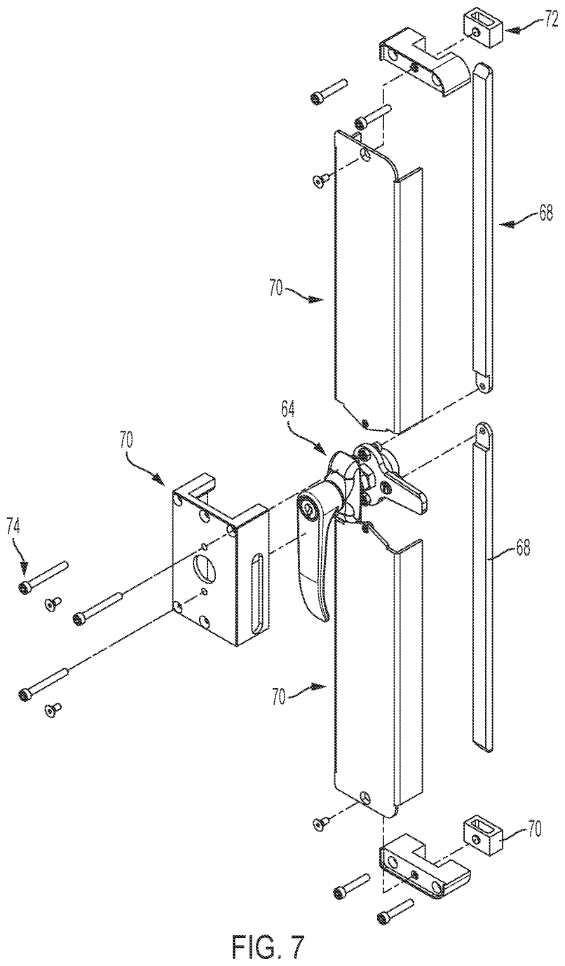

The interconnection ports exclude electromagnetic energy from entering the inside of the rack system, and the means of accomplishing this can be the use of any suitable form of gasketing, fingerstock, conductive pastes, or any other method that can support electromagnetic shielding and facilitate the removal of the interconnection port cover to support any configuration or change in configuration of racks over the life-cycle of the systems protected by the rack system. As best shown in FIG. 7, with the cover 26 removed, the interconnection port 26A is exposed, and has an array of holes 27 that also mate with matching aligned holes in the interconnection port of another rack 10. With the covers 26 removed, the aligned holes can receive screws, bolts or any other suitable connection with, as noted above, suitable gasketing, fingerstock, conductive pastes or other electromagnetic shielding. Actual connection of components may be by any suitable plug, cable, wire and jumper cable without regard to whether it is male/male, male/female, female/female or a unitary connector.

The electromagnetically protected umbilical can also support the supply of power to the rack system and can be connected to an electromagnetically sealed generator dedicated to the support of the rack system and any associated mechanical systems, such as the cooling pedestal/mechanical module.

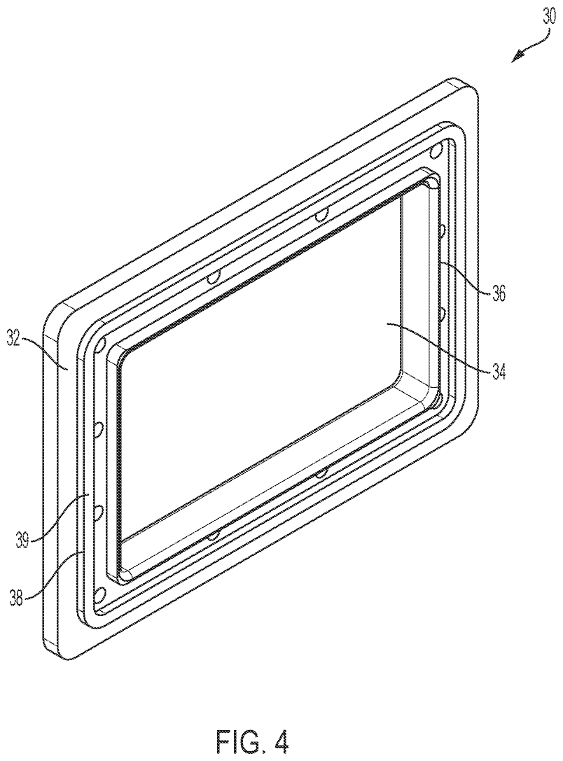

A plenum 30 connects the racks together. As seen in FIG. 4, plenum includes a base 32 with a central opening 34. An inner projection 36 extends about the central opening 34 and a central projection 38 extends from the base at position between the central opening and the periphery of the base. A plurality of apertures 39 are arranged in the space between the inner projection 36 and central projection 38. However, the placement of the central projection and apertures can be varied.

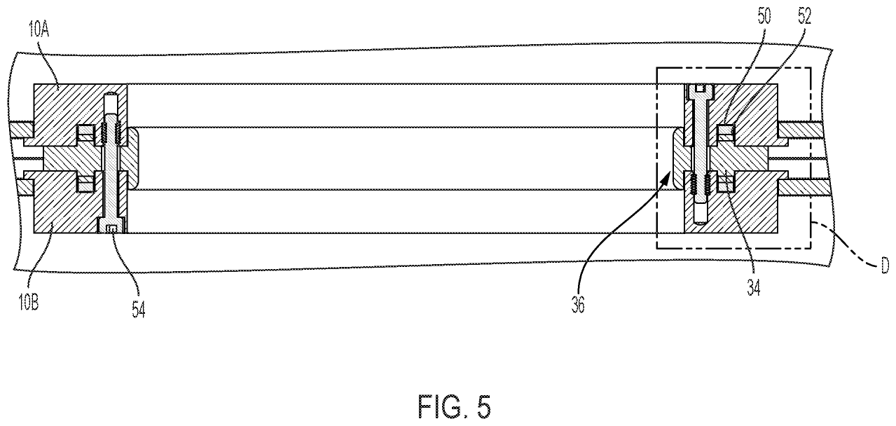

The plenum attached to two racks 10A, 10B can be seen in FIG. 5. The plenum can be made of any suitable material, such as aluminum, steel or stainless steel. When the plenum attaches to the racks, the central projection fits within the interconnection ports of each rack, preferable contacting the edge of the interconnection ports. The central projection fits within a groove 50 formed around each interconnection ports. A gasket 52 further increases the fit between the plenum and racks. Although the plenum can be dimensioned to fit tightly to the interconnection ports, fasteners 54, such as bolts, secure the racks together by extending through the racks and plenum. As seen in FIG. 5, the fasteners extend from the inside of a first rack, trough the apertures 39 and into the second rack. To enhance the security of the connection, it is preferred that the fasteners extend in both directions, with some fasteners extending from the first rack to the second rack and other fasteners extending from the second rack to the first rack.

Rack 10 includes an access door that results in a more efficient operation along with increased performance over its operational lifetime. The door 60 may include mechanical or electronic locks, verification means to include/exclude access to the racks 10. The door 60 is robust so that it cannot be easily penetrated by any unauthorized person. The door 60 seats up against a door gasket 66 or other electromagnetic barrier directly without the typical “pinching” that is part of a typical hinged door. This allows the electronic barrier to be more maintainable, last longer and maintain a higher electromagnetic shielding performance characteristic than a typical electromagnetically shielded door/hatch.

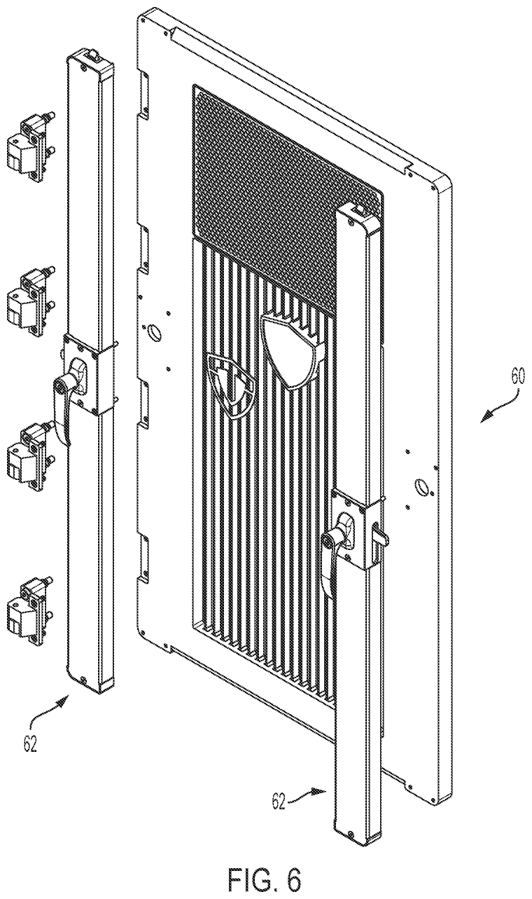

A latch 60 extends along each side of the door, as seen in FIG. 6. FIG. 7 is an exploded view of the latch. The latch includes a handle 64 rotating a horizontal bar when rotating as well as causing the vertical reciprocation of latch bars 68. A guide block 72 at each end of the latch bars keeps the latch bars in place. Covers 70 secured with fasteners 74 cover the moving parts of the latch to protect the parts from damage.

When the latch bars move toward the door frame of the rack, the latch bars extend into an aperture or recess in the door frame to secure the door to the rack body. The ends of the latch bars are beveled so that the front edge of the latch bar engages the aperture or recess. The increasing width of the beveled surface pushes the latch bar inwardly toward the rack body. The gasket 66 about the door frame of the rack body compresses under the force created by the door being biased inwardly by the larch bars. The tight fit between the door 60 and rack body further secures the contents of the rack.

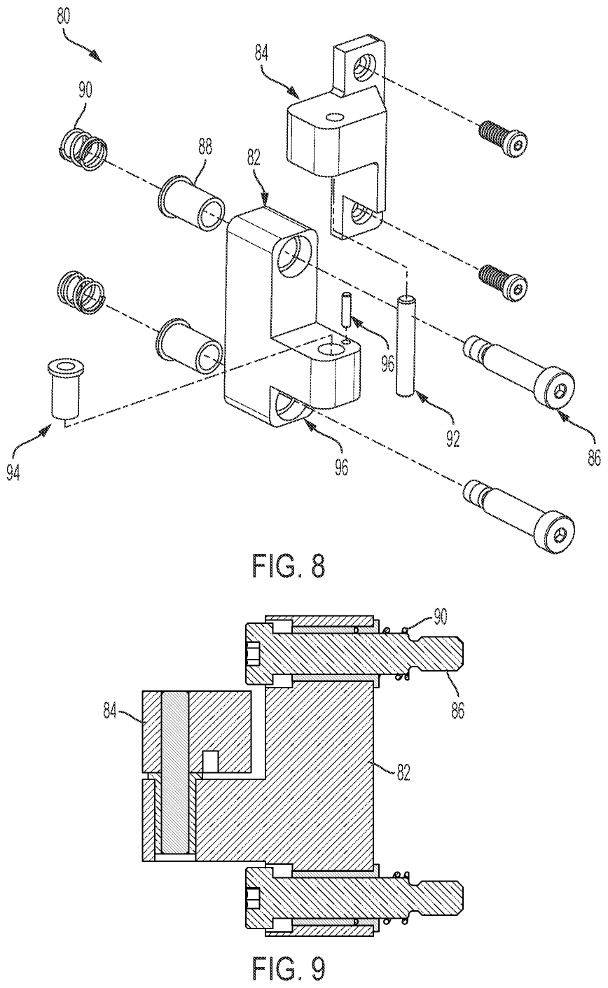

To further create a seal between the door and rack body, the door is connected to the rack body by a floating hinge as depicted in FIGS. 8 and 9. The hinge 80 has a rack portion 82 secured to the rack body and a door portion 84 secured to the door. A hinge pin 92 resting in a cup 94 allows relative rotation between the two portions. A stop 96 can be used to limit the amount of rotation of the door portion.

The rack portion 82 is secured to the rack body by fasteners 86 extending through sleeves 88 which allow movement of the rack portion relative to the rack body. The rack portion may fit within a recess in the door frame. AS spring biases the door portion outwardly. When the door is biased inwardly by the beveled edge of the latch bars engaging the door frame, the gasket compresses and the hinge moves inwardly.

A data center equipment rack and rack system according to the invention has been described with reference to specific embodiments and examples. Various details of the invention may be changed without departing from the scope of the invention. Furthermore, the foregoing description of the preferred embodiments of the invention and best mode for practicing the invention are provided for the purpose of illustration only and not for the purpose of limitation, the invention being defined by the claims.

We claim:

1. An equipment rack, comprising:
a housing having a plurality of walls forming an enclosure;
a port formed in a first wall of the plurality of walls, the port having an edge extending between an inner surface and an outer surface of the first wall;
a plenum attached to the first wall, the plenum having a central opening and surrounding the port.

2. The equipment rack of claim 1, wherein the plenum comprises:
a base having an upper surface and a lower surface; and
an inner projection around the central opening and extending from the lower surface of the of the base,
wherein the inner projection extends into the port and contacts the edge of the port.

3. The equipment rack of claim 2, further comprising a groove in the outer surface of the first wall around the port,
wherein the plenum further comprises a central projection extending from the lower surface of the base,
wherein the central projection extends into the groove.

4. The equipment rack of claim 3, further comprising a gasket in the groove.

5. The equipment rack of claim 1, further comprising a groove in the outer surface of the first wall around the port,
wherein the plenum further comprises:
a base having an upper surface and a lower surface; and
a central projection extending from the lower surface of the base,
wherein the central projection extends into the groove.

6. The equipment rack of claim 5, further comprising a gasket in the groove.

7. An equipment rack system, comprising:
a first housing having a plurality of walls forming an enclosure, a first port formed in a first wall of the plurality of walls, the port having an edge extending between an inner surface and an outer surface of the first wall;
a second housing having a plurality of walls forming an enclosure, a second port formed in a first wall of the plurality of walls, the port having an edge extending between an inner surface and an outer surface of the first wall
a plenum attached to the first wall of the first housing and the first wall of the second housing, the plenum having a central opening and surrounding the port in the first housing and the port of the second housing.

8. The equipment rack system of claim 7, wherein the plenum comprises a base having an upper surface and a lower surface;
an inner projection around the central opening and extending from the lower surface of the of the base,
wherein the inner projection extends into the first port and the second port

9. The equipment rack of claim 8, further comprising a first groove in the outer surface of the first wall of the first housing and a second groove in the outer surface of the first wall of the second housing,
wherein the plenum further comprises a central projection extending from the upper surface and the lower surface of the base,
wherein the central projection extends into the first groove and the second groove.

10. The equipment rack of claim 8, further comprising first fasteners extending from inside the first housing, through first fastening holes in the plenum and into the second housing.

11. The equipment rack of claim 10, further comprising second fasteners extending from inside the first housing, through second fastening holes in the plenum and into the first housing.

12. The equipment rack system of claim 7, further comprising a first groove in the outer surface of the first wall of the first housing and a second groove in the outer surface of the first wall of the second housing,
wherein the plenum comprises:
a base having an upper surface and a lower surface;
a central projection extending from the upper surface and the lower surface of the base,
wherein the central projection extends into the first groove and the second groove.

13. An equipment rack, comprising a housing having a plurality of walls forming an enclosure;
a opening formed in a first wall of the plurality of walls;
a door attached to the housing and covering the opening;
a latch on each of a first side and a second side of the door, each latch comprising:
a rotatable handle, a first latch bar connected to and extending upward from the handle, and a second latch bar connected to and extending downward from the handle, each latch bar engaging an aperture in the housing to bias the door toward the housing.

14. The equipment rack of claim 13, wherein an end of each latch bar is beveled, and
wherein engagement of the beveled end with the aperture in the housing creates a force to bias the door toward the housing.

15. The equipment rack of claim 14, further comprising a guide surrounding each latch bar.

16. The equipment rack of claim 13, wherein the hinge comprises:
a rack portion attached to the housing;
a door portion attached to the door and rotatable connected to the rack portion;
at least one fastener extending through an opening in the rack portion,
a sleeve, the sleeve in the opening of the rack portion and surrounding the at least one fastener, the rack portion slidable relative to the sleeve; and
a spring between the rack portion and housing, the spring biasing the rack portion away from the housing,

17. The equipment rack of claim 16, wherein the at least one fastener extends through the spring.
